(19) United States
(12) Patent Application Publication
(10) Pub. No.: US 2021/0015007 A1
(43) Pub. Date: Jan. 14, 2021

(54) ELECTRONIC APPARATUS HAVING A THERMAL MODULE

(71) Applicant: LENOVO (SINGAPORE) PTE. LTD., Singapore (SG)

(72) Inventors: Ryota Watanabe, Kanagawa (JP); Hiroshi Yamazaki, Kanagawa (JP); Misa Shimada, Kanagawa (JP)

(21) Appl. No.: 16/924,093

(22) Filed: Jul. 8, 2020

(30) Foreign Application Priority Data
Jul. 8, 2019 (JP) 2019-127032

(51) Int. Cl. H05K 7/20; G06F 1/20

(52) U.S. Cl. CPC H05K 7/20481; H05K 7/20454; G06F 1/203

(57) ABSTRACT

A thermal module for suppressing surface temperature of a chassis is disclosed. The thermal module includes a flexible heat conductive sheet, a frame having openings covered by the heat conductive sheet, and a heat pipe that contacts the heat conductive sheet through various openings of the frame.

### PRIORITY CLAIM

The present application claims benefit of priority under 35 U.S.C. §§ 120, 365 to the previously filed Japanese Patent Application No. JP2019-127032 with a priority date of Jul. 8, 2019, which is incorporated by reference herein.

### TECHNICAL FIELD

The present invention relates to thermal modules in general, and in particular to an electronic apparatus having a thermal module.

### BACKGROUND

An electronic apparatus, such as a portable laptop personal computer, includes a board on which electronic components are mounted, and a thermal module that transports heat away from the electronic components. The thermal module includes a heat sink that diffuses and dissipates heat emitted from the electronic components.

Because of thinner electronic apparatuses in recent years, heat generated by electronic components tends to easily affect the surface temperature of a chassis. For example, the surface temperature of a chassis rises in the vicinity of electronic components that generate a large amount of heat. While it is effective to place a heat sink on top of heat-generating components, a copper plate heat sink tends to be relatively thick, which results in a narrower gap with respect to the chassis, thus causing the surface temperature of the chassis to increase.

Consequently, it would be desirable to provide a thermal module that is capable of suppressing a rise in the surface temperature of a chassis in the vicinity of electronic components that generate a large amount of heat.

### SUMMARY

In accordance with an embodiment of the present disclosure, a thermal module includes a flexible heat conductive sheet, a frame having an opening closed by the heat conductive sheet, and a heat transport member that contacts the heat conductive sheet through an opening of the frame.

All features and advantages of the present disclosure will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is an external view of an electronic apparatus, according to one embodiment;

FIG. 2 is a perspective view of a thermal module, according to one embodiment;

FIG. 3 is an exploded perspective view of the thermal module from FIG. 2, according to one embodiment:

FIG. 4 is a diagram of a frame, according to one embodiment, observed from a heat conductive sheet side;

FIG. 5 is a perspective view of the frame from FIG. 4, according to one embodiment, observed from the side opposite the heat conductive sheet; and

FIG. 6 is a cross-sectional view taken along line A-A illustrated in FIG. 2.

### DETAILED DESCRIPTION

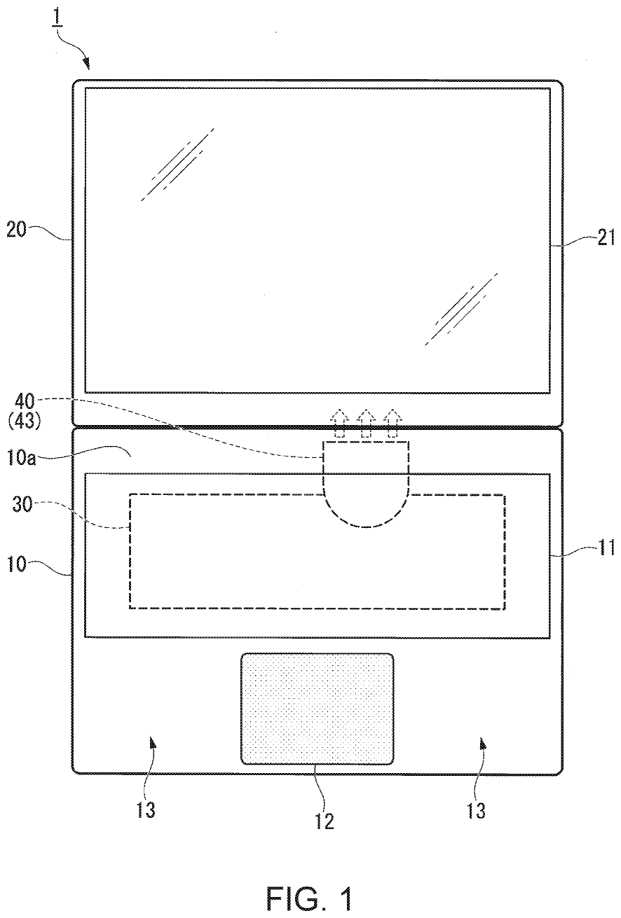

FIG. 1 is an external view of an electronic apparatus 1, according to one embodiment. The electronic apparatus 1 includes a chassis 10 and a lid 20. The electronic apparatus 1 is a clamshell type laptop personal computer (so-called notebook type personal computer). The electronic apparatus 1 may be a tablet or a smart phone instead of the clamshell type.

The chassis 10 is shaped like a flat box. A keyboard 11 and a touch pad 12 are provided on an upper surface 10a of the chassis 10. The keyboard 11 is placed on the back side of the upper surface 10a, and the touch pad 12 is placed on the front side of the upper surface 10a. Palm rest portions 13 are formed on both left and right sides of the touch pad 12 in the upper surface 10a.

The lid 20 is provided with a display unit 21 on a surface opposed to the upper surface 10a of the chassis 10. The display unit 21 is formed of, for example, a liquid crystal display or an organic EL display. The lower end portion of the lid 20 is rotatable about an axis extending in the lateral direction through a hinge (not illustrated) and is connected to the back side of the chassis 10.

When the lid 20 is opened as illustrated in FIG. 1, the upper surface 10a of the chassis 10 is placed in an open state. Meanwhile, when the lid 20 is closed, the lid 20 becomes a cover that covers the display unit 21 and the upper surface 10a of the chassis 10.

Provided inside the chassis are a motherboard 30 and a thermal module 40 and the like, which will be discussed hereinafter. An exhaust port (not illustrated) is provided at the back side of the chassis 10, so that an exhaust flow of a cooling fan 43 of the thermal module 40 is exhausted to the back surface side of the lid 20. The chassis 10 has an intake port or a gap (not illustrated) formed to take external air into the chassis 10. The exhaust flow of the thermal module 40 may be exhausted toward a side surface or the like rather than toward the back surface side of the lid 20.

The motherboard 30 is fixed by screwing to a group of bosses (not illustrated) provided on the chassis 10 and is placed being opposed substantially in parallel to the bottom of the chassis 10 with a space provided therebetween. The motherboard 30 is placed on the rear surface side of the keyboard 11.

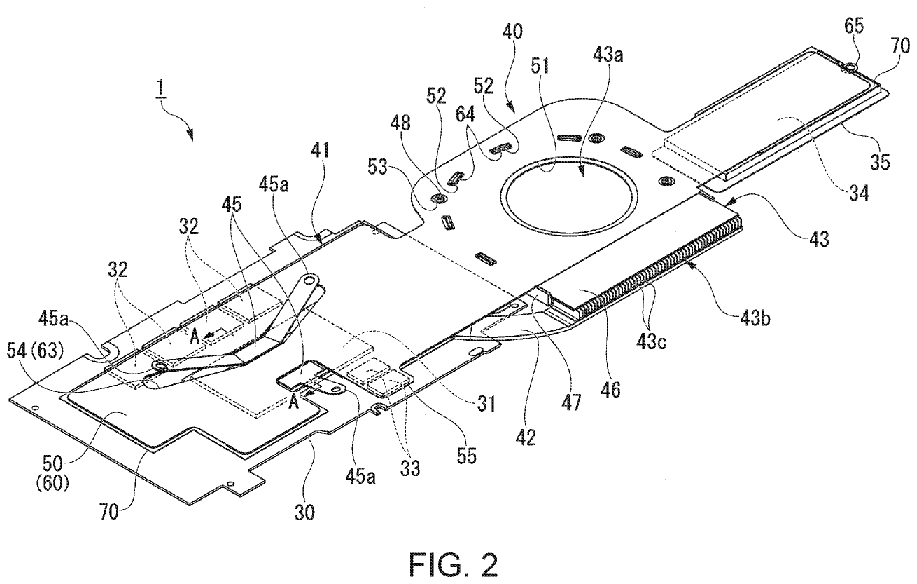

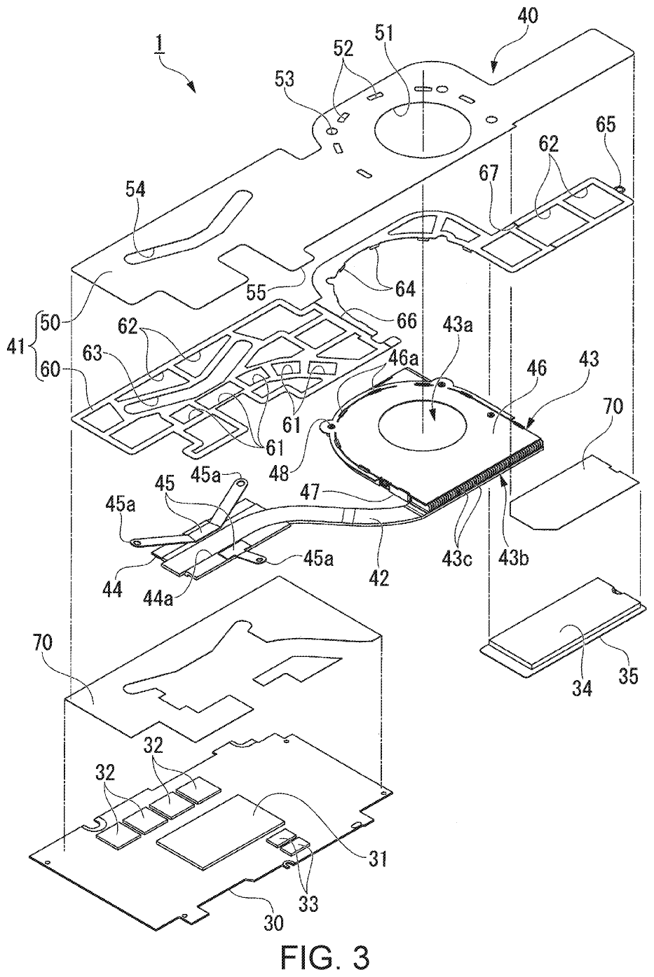

FIG. 2 is a perspective view of the thermal module 40, according to one embodiment. FIG. 3 is an exploded perspective view of the thermal module 40, according to one embodiment.

As illustrated in FIG. 2, the thermal module 40 is placed, overlapping the motherboard 30 and overlapping a sub-board 35 not illustrated in FIG. 1.

As illustrated in FIG. 3, a set of electronic components (the electronic components illustrated in the drawings being some of the major components) are mounted on the motherboard 30. Among the electronic components, the ones that generate a relatively large amount of heat (heat-generating components) are, for example, a CPU (central processing unit) 31 (a first heat-generating component), a memory 32 (a second heat-generating component), and a DC/DC converter 33 (a third heat-generating component). Further, a solid state drive (SSD) 34 (a second heat-generating component) is mounted as a heat-generating component on the sub-board 35. These heat-generating components are merely examples, and other heat-generating components, such as a graphics processing unit (GPU) and a wireless wide-area network card, may be included.

The thermal module 40 has a heat sink 41 (a heat sink for thermal module), a heat pipe 42 (a heat transport member), and the cooling fan 43. The cooling fan 43 is a centrifugal fan and includes an intake port 43a in the axial direction and an exhaust port 43b in the radial direction orthogonal to the axial direction. The exhaust port 43b is provided with multiple heat dissipation fins 43c. The heat dissipation fins 43c thermally contact one end of the heat pipe 42.

The other end of the heat pipe 42 extends to a position where the other end overlaps the CPU 31. An expansion member 44, which expands the area receiving heat from the CPU 31, is fixed to the other end of the heat pipe 42. Biasing members 45 are fixed to the expansion member 44. The expansion member 44 is formed of a metal block having high heat conductivity (e.g. a copper block). The biasing members 45 are formed of, for example, stainless steel leaf springs.

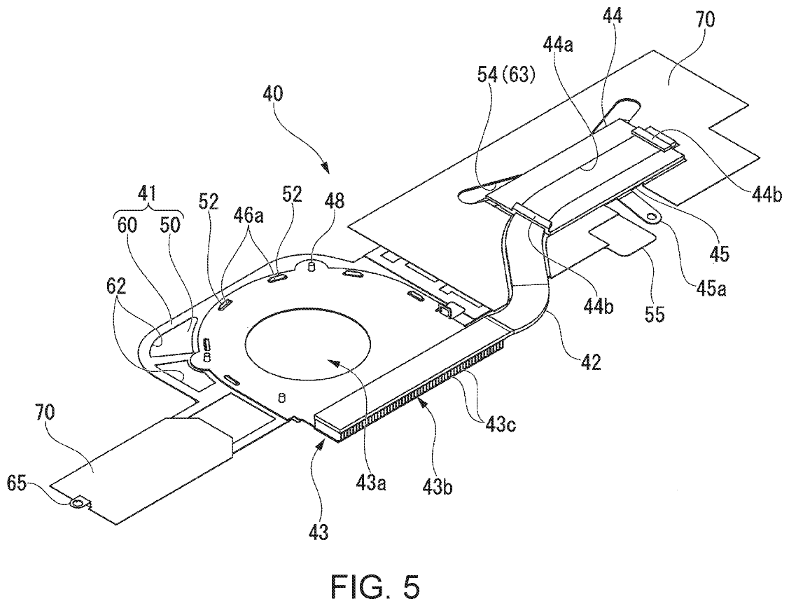

In the expansion member 44, a slit 44a is formed to place the heat pipe 42, the slit 44a separating the expansion member 44 into two blocks. The two blocks are interconnected by two connection pieces 44b across the slit 44a, as illustrated in FIG. 5 (a view in the opposite direction from that of FIG. 3), which will be discussed hereinafter.

The biasing members 45 have fixing portions 45a that can be screwed to the chassis 10. As illustrated in FIG. 2, the fixing portions 45a are disposed at three places around the CPU 31. This enables the biasing members 45 to substantially evenly press the heat pipe 42 and the expansion member 44 against the CPU 31.

The heat sink 41 includes a flexible heat conductive sheet 50 and a frame 60 which has openings 61, 62 closed by the heat conductive sheet 50, as illustrated in FIG. 3. The heat conductive sheet 50 is formed of, for example, a graphite sheet. The frame 60 is formed of, for example, a stainless steel frame.

The heat sink 41 is attached to the motherboard 30 and the sub-board 35 through the intermediary of an adhesive sheet 70. The adhesive sheet 70 is placed overlapping the memory 32 and the SSD 34 among the heat-generating components, while not overlapping the CPU 31 and the DC/DC converter 33. The adhesive sheet 70 placed on the motherboard 30 is cut along the shapes of the heat pipe 42, the expansion member 44, and the biasing members 45 described above.

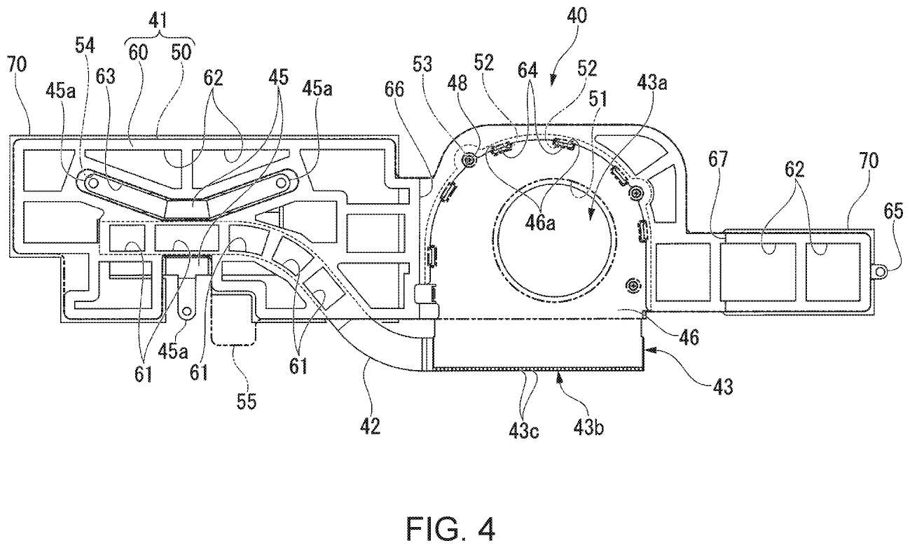

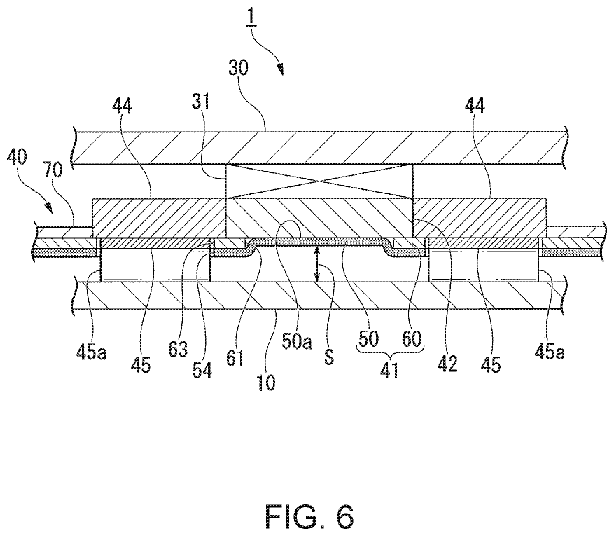

FIG. 4 is a diagram illustrating the frame 60, according to one embodiment, which is observed from the heat conductive sheet 50 side. In FIG. 4, only the outline of the heat conductive sheet 50 is illustrated so as to improve the visibility of the frame 60. FIG. 5 is a perspective view of the frame 60, according to one embodiment, observed from the side opposite the heat conductive sheet 50. FIG. 5 illustrates only a fan cover 46, with a fan casing 47 constituting a part of the chassis of the cooling fan 43 removed. FIG. 6 is a cross-sectional view taken along line A-A illustrated in FIG. 2.

As illustrated in FIG. 4, a set of openings 61, 62 and 63 are formed in the frame 60. Among the openings 61, 62 and 63, the first openings 61 are intermittently formed along the heat pipe 42 in a part that overlaps the heat pipe 42. The first openings 61 are formed to be substantially rectangular openings, each of which has a slightly smaller width than the width of the heat pipe 42, arranged in a row along the meandering shape of the heat pipe 42.

More specifically, the first openings 61 are formed at a substantially constant pitch along the longitudinal direction of the heat pipe 42, but are exceptionally longer than the pitch in a portion sandwiched by the biasing members 45 (a portion overlapping the CPU 31). Further, the first openings 61 in a bent portion of the heat pipe 42 have fan shapes. These first openings 61 are closed by the heat conductive sheet 50. Further, the heat pipe 42 contacts the heat conductive sheet 50 through the first openings 61.

The second openings 62 are openings formed in a portion that does not overlap the heat pipe 42. The second openings 62 have opening edges (crosspieces) vertically and horizontally, independent of the heat pipe 42. These second openings 62 are closed by the heat conductive sheet 50. On the opposite side of the second opening 62 overlapping the motherboard 30 and the sub-board 35 from the heat conductive sheet 50, adhesive sheets 70 are disposed, as illustrated in FIG. 5.

The third opening 63 is a substantially V-shaped opening formed in a portion overlapping the biasing members 45. The third opening 63 is closed by neither the heat conductive sheet 50 nor by the adhesive sheet 70.

In the frame 60, extremely small steps 66, 67 are formed, as illustrated in FIG. 3 and FIG. 4. The step 66 is a step for adjusting the height of a portion overlapping the cooling fan 43. Further, the step 67 is a step for adjusting the height of a portion overlapping the SSD 34. The frame 60 is provided with a fixing portion 65, which projects and which can be tightened together with the sub-board 35, at a portion overlapping the SSD 34.

The frame 60 has engaging claws 64, which engage with the cooling fan 43, at a portion overlapping the cooling fan 43. The engaging claws 64 are formed by bending a part of the frame 60, and are formed in a multiple number along the peripheral edge of the fan cover 46 of the cooling fan 43. A set of engaging holes 46a, in which the engaging claws 64 are inserted, are formed in the peripheral edge of the fan cover 46.

Formed in the heat conductive sheet 50 are a first through hole 51 for exposing the intake port 43a of the cooling fan 43, second through holes 52 for exposing the engaging claws 64 of the frame 60 and the engaging holes 46a of the fan cover 46, a third through hole 53 for exposing a fixing bolt 48 that secures the fan cover 46 and the fan casing 47, and a fourth through hole 54 for exposing the biasing members 45, as illustrated in FIG. 2 and FIG. 3.

One surface 50a of the heat conductive sheet 50 that is opposed to the frame 60 (refer to FIG. 6) is an adhesive surface, and the frame 60, the heat pipe 42, and the cooling fan 43 are attached to the one surface 50a. In other words, the opening edges (crosspieces) of the frame 60, the heat pipe 42 exposed through the first openings 61, and the fan cover 46 of the cooling fan 43 overlapping the heat conductive sheet 50 are attached to the one surface 50a of the heat conductive sheet 50.

The heat conductive sheet 50 has an extension portion 55 (refer to FIG. 2 and FIG. 4) extending outwardly from the frame 60 in a portion overlapping the motherboard 30. The extension portion 55 is attached to the DC/DC converter 33, which is taller among the heat-generating components. In other words, the extension portion 55 is in direct contact with the DC/DC converter 33 without going through the frame 60 and the adhesive sheet 70.

The heat sink 41 of the thermal module 40 having the configuration described above includes the flexible heat conductive sheet 50 and the frame 60 having the openings 61, 62 closed by the heat conductive sheet 50, thus making it possible to secure the function for heat conduction by the thin heat conductive sheet 50 and to maintain the shape of the heat conductive sheet 50 by the frame 60.

The heat conductive sheet 50 has flexibility, so that the heat conductive sheet 50 can warp in the openings 61 of the frame 60 so as to contact the heat pipe 42, as illustrated in FIG. 6. This makes it possible to secure a large space S between the heat sink 41 (the heat conductive sheet 50) and the chassis 10 at immediately below the CPU 31 causing one of the hot spots. As a result, arise in the surface temperature of the chassis 10 is suppressed.

Thus, according to the thermal module 40 of the present embodiment described above, the configuration is adopted, which includes the flexible heat conductive sheet 50, the frame 60 having the openings 61 closed by the heat conductive sheet 50, and the heat pipe 42 in contact with the heat conductive sheet 50 through the openings 61 of the frame 60. This provides the thermal module 40 capable of suppressing a rise in the surface temperature of the chassis 10 in the vicinity of electronic components that generate a large amount of heat.

Further, in the present embodiment, the heat conductive sheet 50 is a graphite sheet, which provides thermal diffusivity equivalent to that of, for example, a conventional copper sheet while the thickness is approximately half the thickness of the copper sheet. Therefore, the heat conductive sheet 50 can be thinned to, for example, approximately 0.1 mm.

Further, in the present embodiment, the frame 60 is a stainless steel frame. The stainless steel frame has low thermal conductivity, but can maintain strength even when the frame is lighter-weight and thinner, and is therefore ideally used to maintain the shape of the heat conductive sheet 50. The stainless steel frame can also be thinned to, for example, approximately 0.1 mm.

Further, in the present embodiment, the frame 60 has the first openings 61 arranged intermittently along the heat pipe 42 in the portion overlapping the heat pipe 42, as illustrated in FIG. 4. This makes it possible to secure a large area of contact between the heat conductive sheet 50 and the heat pipe 42 while keeping the shape of the heat conductive sheet 50 at the same time so as to make it easy to transmit the heat received by the heat conductive sheet 50 to the heat pipe 42.

Further, in the present embodiment, the frame 60 has the second openings 62, which are closed by the heat conductive sheet 50, in a portion that does not overlap the heat pipe 42, so that the heat can also be conducted away from other heat-generating components in a portion not overlapping the heat pipe 42.

Further, according to the present embodiment, in the frame 60, the portion overlapping the cooling fan 43 has the engaging claws 64, which engage the cooling fan 43, thus enabling the frame 60 (the heat sink 41) to be easily positioned with respect to the cooling fan 43. This leads to improved assemblability of the thermal module 40.

Further, in the present embodiment, the one surface 50a of the heat conductive sheet 50 is an adhesive surface, and the frame 60, the heat pipe 42, and the cooling fan 43 are attached to the one surface 50a. This configuration leads to improved assemblability of the thermal module 40. For example, if both surfaces of the heat conductive sheet 50 are adhesive surfaces, and the frame 60 is attached to one surface and the heat pipe 42 and the cooling fan 43 are attached to the other surface, then the man-hours of the attaching process increase, while attaching the frame 60, the heat pipe 42, and the cooling fan 43 to the one surface 50a of the heat conductive sheet 50 decreases the man-hours of the attaching process, and only one adhesive surface is required.

Further, the electronic apparatus 1 includes, as a heat-generating component, the CPU 31 (the first heat-generating component) placed overlapping the heat pipe 42, thus making it possible to suppress a rise in the surface temperature of the chassis 10 in the vicinity of the CPU 31 generating a large amount of heat.

Further, in the present embodiment, the second heat-generating components, such as the memory 32 and the SSD 34, which do not overlap the heat pipe 42 and which contact the heat conductive sheet 50 through the second openings 62, are provided as heat-generating components, so that heat can also be transmitted to and diffused by the heat conductive sheet 50 from the memory 32, the SSD 34 and the like, which generate a large amount of heat.

Further, in the present embodiment, the heat conductive sheet 50 has the extension portion 55, which extends outwardly from the frame 60, and includes, as a heat-generating component, the DC/DC converter 33 (the third heat-generating component), which contacts the extension portion 55, thus enabling heat to be directly transmitted to and diffused by the heat conductive sheet 50 also from the DC/DC converter 33, which generates a large amount of heat and which is tall.

The above has described in detail the embodiment of the present invention with reference to the accompanying drawings; however, specific configurations are not limited to those of the above-described embodiment, and include designs and the like that are within the scope of the gist of the present invention. The configurations described in the above-described embodiment can be optionally combined insofar as the combinations are not contradictory.

For example, in the above-described embodiment, the configuration in which the heat conductive sheet 50 is a graphite sheet has been illustrated. Alternatively, however, the heat conductive sheet 50 may be, for example, a silicone-based heat conductive sheet or a nonsilicone-based (e.g., acrylic) heat conductive sheet.

Further, for example, in the above-described embodiment, the configuration in which the frame 60 is a stainless steel frame has been illustrated. Alternatively, however, the frame 60 may be made of any other metal, such as titanium, titanium alloy, aluminum, aluminum alloy, copper, or copper alloy. Further, the frame 60 may be a plastic frame (including a fiber-reinforced plastic frame) insofar as strength can be ensured.

Further, for example, in the above-described embodiment, the CPU 31, the memory 32, the DC/DC converter 33, and the SSD 36 have been illustrated as the heat-generating components. However, any other electronic components (e.g. a charger) may be included as the heat-generating components. Further, the designation of the first to the third heat-generating components is not limited to the above-described heat-generating components.

Further, for example, in the above-described embodiment, the heat pipe 42 has been illustrated as the heat transport member; however, the heat transport member may alternatively be, for example, a vapor chamber.

As has been described, the present invention provides an electronic apparatus having a thermal module capable of suppressing a rise in the surface temperature of a chassis in the vicinity of electronic components that generate a large amount of heat.

While the invention has been particularly shown and described with reference to a preferred embodiment, it will be understood by those skilled in the art that various changes in form and detail may be made therein without departing from the spirit and scope of the invention.

What is claimed is:

1. A thermal module comprising:
a flexible heat conductive sheet;
a frame having an opening covered by said heat conductive sheet; and
a heat transport member contacting said heat conductive sheet through said opening of said frame.

2. The thermal module of claim 1, wherein said heat conductive sheet is made of graphite.

3. The thermal module of claim 1, wherein said frame is made of stainless steel.

4. The thermal module of claim 1, wherein said frame having said opening intermittently along said heat transport member in a portion overlapping said heat transport member.

5. The thermal module of claim 4, wherein said frame further includes a second opening, covered by said heat conductive sheet, located in a portion not overlapping said heat transport member.

6. The thermal module of claim 1, further comprising a cooling fan for cooling said heat transport member.

7. The thermal module of claim 6, wherein said frame includes, in a portion overlapping said cooling fan, an engaging claw that engages said cooling fan.

8. The thermal module of claim 6, wherein said cooling fan is a centrifugal fan having an intake port in an axial direction and an exhaust port in a radial direction orthogonal to said axial direction.

9. The thermal module of claim 1, wherein one surface of said heat conductive sheet is an adhesive surface.

10. The thermal module of claim 9, wherein said frame, said heat transport member, and a cooling fan are attached to said adhesive surface.

11. An electronic apparatus, comprising:
a board on which a heat-generating component is mounted; and
a thermal module having
a flexible heat conductive sheet;
a frame having an opening covered by said heat conductive sheet; and
a heat transport member contacting said heat conductive sheet through said opening of said frame.

12. The electronic apparatus of claim 11, further comprising, as said heat-generating component, a first heat-generating component placed overlapping said heat transport member.

13. The electronic apparatus of claim 11, further comprising, as said heat-generating component, a second heat-generating component that does not overlap said heat transport member and contacts said heat conductive sheet through said opening.

14. The electronic apparatus of claim 11, wherein said heat conductive sheet has an extension portion that extends outwardly from said frame.

15. The electronic apparatus of claim 14, wherein said electronic apparatus including, as said heat-generating component, a third heat-generating component that contacts said extension portion.

16. The electronic apparatus of claim 11, further comprising a frame having an opening covered by said heat conductive sheet.
